(19) United States
(12) Patent Application Publication
(10) Pub. No.: US 2012/0319157 A1
(43) Pub. Date: Dec. 20, 2012

(54) PHOTOELECTRIC CONVERSION DEVICE

(75) Inventors: Mitsuhiro Ichuo, Zama (JP); Toshiya Endo, Isehara (JP); Sho Kato, Atsugi (JP)

(73) Assignee: SEMICONDUCTOR ENERGY LABORATORY CO., LTD., Atsugi-shi (JP)

(21) Appl. No.: 13/488,480

(22) Filed: Jun. 5, 2012

(30) Foreign Application Priority Data
Jun. 14, 2011 (JP) 2011-132101

(51) Int. Cl. H01L 33/36; H01L 31/0224

(52) U.S. Cl. 257/99; 257/431; 257/E31.124; 257/E33.062

(57) ABSTRACT

To provide a heterojunction photoelectric conversion device including passivation layers for reducing surface defects of a silicon substrate. The photoelectric conversion device includes a first silicon semiconductor layer which is in contact with one surface of a single crystal silicon substrate; a second silicon semiconductor layer which is in contact with the first silicon semiconductor layer; a third silicon semiconductor layer which is in contact with the other surface of the single crystal silicon substrate; and a fourth silicon semiconductor layer which is in contact with the third silicon semiconductor layer. Further, the fluorine concentration in the first silicon semiconductor layer and the third silicon semiconductor layer is lower than or equal to 1×10¹⁷ atoms/cm³.

### BACKGROUND OF THE INVENTION

1. Field of the Invention

The present invention relates to a photoelectric conversion device.

2. Description of the Related Art

In recent years, a photoelectric conversion device has attracted attention as a device for producing clean energy, which can reduce the amount of carbon dioxide emissions, for example. As a typical example of a photoelectric conversion device, a solar cell which uses a silicon substrate of single crystal silicon, polycrystalline silicon, or the like has been known, and has been actively researched and developed in order to enhance the conversion efficiency thereof.

In a solar cell using a silicon substrate, a p-type silicon substrate is often used. The diffusion length of carriers in a p-type silicon substrate is longer than that of an n-type silicon substrate, so that minority carriers generated in a p-type silicon substrate are likely to be efficiently collected.

Although boron is generally used as an impurity imparting p-type conductivity to a silicon substrate, when boron coexists with oxygen in the silicon substrate, a deep level is formed, and thus the carriers are likely to be trapped by the level. Therefore, the lifetime is decreased. This phenomenon is called light degradation, which is one factor decreasing the conversion efficiency of a solar cell.

As a countermeasure against the above phenomenon, Patent Document 1 discloses a technique using a silicon substrate in which an impurity imparting p-type conductivity is gallium and the oxygen concentration is low.

On the other hand, an n-type silicon substrate which does not contain boron does not have a factor of light degradation. Further, in general, the capture cross section of electrons is larger than that of holes by an influence of impurity contamination in a silicon substrate; therefore, when the amount of contamination is sufficiently low, an n-type silicon substrate can have a longer lifetime. Accordingly, a solar cell using an n-type silicon substrate has also been developed recently.

### REFERENCE

### Patent Document

[Patent Document 1] Japanese Published Patent Application No. 2002-57351

### SUMMARY OF THE INVENTION

However, the effective lifetime of a silicon substrate is strongly affected not only by bulk characteristics but also by the surface defects. Therefore, in order to obtain an effect of improvement of the bulk characteristics, it is important to reduce the surface defects.

In particular, for example, in the case where unevenness is provided on a surface in order to give an optical effect, the surface area is increased, which results in an increase in the absolute amount of surface defects. The surface defects promote surface recombination, which causes a decrease in the effective lifetime.

In other words, surface defects of a silicon substrate are reduced as much as possible, whereby the effective lifetime can be further improved, and electric characteristics of a photoelectric conversion device can be improved. In particular, for the above-described reason, remarkable effects are obtained in the case where an n-type silicon substrate is used.

Accordingly, an object of one embodiment of the present invention is to provide a photoelectric conversion device including passivation layers for reducing surface defects of a silicon substrate.

One embodiment of the present invention disclosed in this specification is a heterojunction photoelectric conversion device including passivation layers for reducing surface defects of a silicon substrate.

One embodiment of the present invention disclosed in this specification is a photoelectric conversion device including, between a pair of electrodes, a single crystal silicon substrate having one conductivity type; a first silicon semiconductor layer which is in contact with one surface of the single crystal silicon substrate; a second silicon semiconductor layer which is in contact with the first silicon semiconductor layer and has a conductivity type opposite to that of the single crystal silicon substrate; a light-transmitting conductive film which is in contact with the second silicon semiconductor layer; a third silicon semiconductor layer which is in contact with the other surface of the single crystal silicon substrate; and a fourth silicon semiconductor layer which is in contact with the third silicon semiconductor layer, has the same conductivity type as the single crystal silicon substrate, and has a higher carrier density than the single crystal silicon substrate. Further, the fluorine concentration in the first silicon semiconductor layer and the third silicon semiconductor layer is lower than or equal to 1×10¹⁷ atoms/cm³.

Note that in this specification and the like, ordinal numbers such as “first” and “second” are used in order to avoid confusion among components, and do not limit the order or number of the components.

The single crystal silicon substrate preferably has n-type conductivity. Further, the oxygen concentration in the single crystal silicon substrate is preferably lower than or equal to 8×10¹⁷ atoms/cm³.

The fluorine concentration in the first silicon semiconductor layer and the third silicon semiconductor layer is preferably lower than the nitrogen concentration in the first silicon semiconductor layer and the third silicon semiconductor layer.

Further, the fluorine concentration in the first silicon semiconductor layer and the third silicon semiconductor layer is preferably lower than the oxygen concentration in the first silicon semiconductor layer and the third silicon semiconductor layer.

By use of one embodiment of the present invention, the effective lifetime of a single crystal silicon substrate can be improved, and electric characteristics of a photoelectric conversion device can be improved.

### BRIEF DESCRIPTION OF THE DRAWINGS

In the accompanying drawings:

FIGS. 1A and 1B are cross-sectional views each illustrating a photoelectric conversion device;

FIG. 2 shows measurement results of lifetimes of samples each including amorphous silicon semiconductor layers which are formed on both surfaces of a single crystal silicon substrate and whose fluorine concentration varies among the samples;

FIG. 3 shows the relation between lifetimes of plural samples each including silicon semiconductor layers which are formed on both surfaces of a single crystal silicon substrate and a difference (C_{N}−C_{F}) between the nitrogen concentration and the fluorine concentration of the silicon semiconductor layers and the relation between the lifetimes of the plural samples and a difference (C_{O}−C_{F}) between the oxygen concentration and the fluorine concentration of the silicon semiconductor layers;

FIGS. 4A to 4C are cross-sectional views illustrating a method for manufacturing a photoelectric conversion device;

FIGS. 5A to 5C are cross-sectional views illustrating the method for manufacturing the photoelectric conversion device;

FIG. 6 shows power density dependence of the fluorine concentration in a silicon semiconductor layer during deposition; and

FIG. 7 shows results obtained by comparing lifetimes of samples in each of which amorphous silicon layers are provided on both surfaces of a single crystal silicon substrate and junction layers are provided on the amorphous silicon layers with open circuit voltages of photoelectric conversion devices each including passivation layers formed under the same conditions as those of the amorphous silicon layers.

### DETAILED DESCRIPTION OF THE INVENTION

Hereinafter, an embodiment and an example of the present invention will be described in detail with reference to the accompanying drawings. However, the present invention is not limited to the description below, and it is easily understood by those skilled in the art that modes and details disclosed herein can be modified in various ways without departing from the spirit and the scope of the present invention. Therefore, the present invention is not construed as being limited to description of the embodiment and the example below. In the drawings for explaining the embodiment and the example, the same portions or portions having similar functions are denoted by the same reference numerals, and description of such portions is not repeated in some cases.

In this embodiment, a structure of a photoelectric conversion device according to one embodiment of the present invention and a method for manufacturing the photoelectric conversion device will be described.

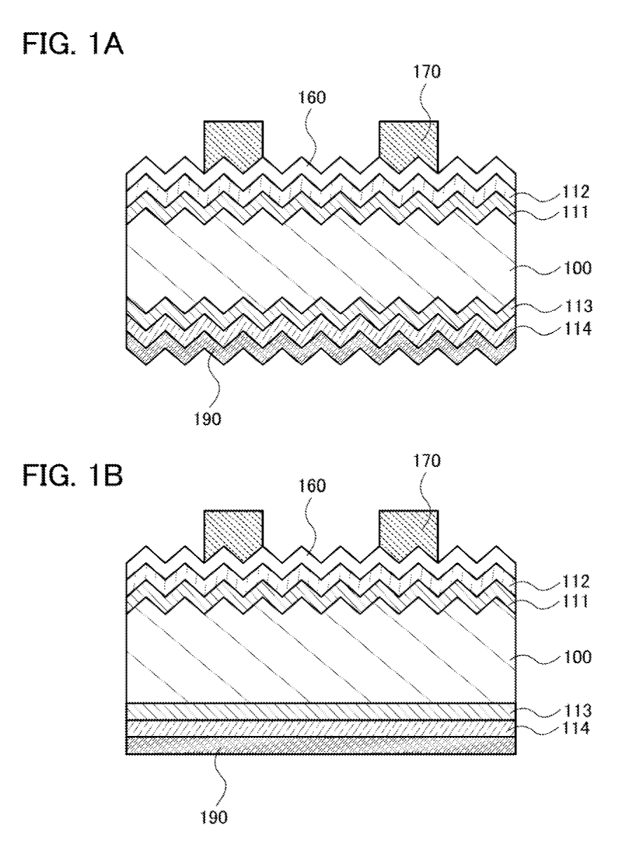

FIGS. 1A and 1B are cross-sectional views each illustrating a photoelectric conversion device according to one embodiment of the present invention. In each of the photoelectric conversion devices, a first silicon semiconductor layer 111, a second silicon semiconductor layer 112, a light-transmitting conductive film 160, and a first electrode 170 are stacked in this order on one surface of a single crystal silicon substrate 100, and a third silicon semiconductor layer 113, a fourth silicon semiconductor layer 114, and a second electrode 190 are stacked in this order on the other surface of the single crystal silicon substrate 100. Note that the first electrode 170 is a grid electrode, and the surface on which the first electrode 170 is formed serves as a light-receiving surface. In addition, the second electrode 190 may also he a grid electrode, and both surfaces on which the first electrode 170 and the second electrode 190 are formed may serve as light-receiving surfaces. In that case, a light-transmitting conductive film is preferably provided between the fourth silicon semiconductor layer 114 and the second electrode 190.

In FIG. 1A, both surfaces of the single crystal silicon substrate 100 each have unevenness in which a distance between projections is several tens of micrometers and whose height is several tens of micrometers. Such a structure can be formed in such a manner that both the surfaces of the single crystal silicon substrate 100 are subjected to etching without using a mask in the etching for forming unevenness in FIG. 1B, only the one surface of the single crystal silicon substrate 100 has unevenness; this structure can be formed in such a manner that the other surface of the single crystal silicon substrate 100 is covered with a mask in the etching for forming unevenness and only the one surface is subjected to etching. Although not illustrated, such unevenness is not necessarily provided on the surfaces of the single crystal silicon substrate 100.

Incident light is reflected in a multiple manner on the surface processed to have unevenness, and travels obliquely in the single crystal silicon substrate; thus, the optical path length is increased. In addition, a so-called light trapping effect in which light reflected by the back surface is totally reflected by the surface can occur.

In one embodiment of the present invention, an n-type single crystal silicon substrate is preferably used as the single crystal silicon substrate 100. Even a single crystal silicon substrate in which impurities are reduced as much as possible contains some impurities, and carries are trapped by levels formed by the impurities. When a p-type single crystal silicon substrate and an n-type single crystal silicon substrate in which the impurity concentrations are sufficiently small and substantially equal to each other are compared, an n-type silicon substrate in which holes are minority carriers has a longer lifetime because the capture cross section of electrons is larger than that of holes.

However, as for a general single crystal silicon substrate, the diffusion length of carriers in a p-type single crystal silicon substrate in which electrons are minority carriers is longer than that of an n-type single crystal silicon substrate. Therefore, in the case of using an n-type single crystal silicon substrate, the thickness of the substrate needs to be made small in accordance with the diffusion length. When the thickness of the substrate is made small, light use efficiency is reduced, which results in a reduction in the short circuit current density.

It is necessary to reduce impurities and defects in order to increase the diffusion length of carriers in an n-type single crystal silicon substrate without a reduction in the thickness of the substrate. In one embodiment of the present invention, an n-type single crystal silicon substrate having a low oxygen concentration is used. For example, an n-type single crystal silicon substrate having an oxygen concentration of lower than or equal to 8×10¹⁷ atoms/cm³, preferably lower than or equal to 5×10¹⁷ atoms/cm³, more preferably lower than or equal to 3×10¹⁷ atoms/cm³ is used. Here, oxygen in single crystal silicon refers to oxygen between lattices. A silicon wafer having a low oxygen concentration as described above can be manufactured by a floating zone (FZ) method, a magnetic field applied czochralski (MCZ) method, or the like. Further, the oxygen concentration can be measured by Fourier transform infrared spectroscopy (a conversion factor of 4.81×10¹⁷/cm²).

The first silicon semiconductor layer 111 and the third silicon semiconductor layer 113 are high-quality i-type semiconductor layers with few defects and can reduce surface defects of the single crystal silicon substrate 100. Note that in this specification, an i-type semiconductor refers to not only a so-called intrinsic semiconductor in which the Fermi level lies in the middle of the band gap, but also a semiconductor in which the concentrations of an impurity imparting p-type conductivity and an impurity imparting n-type conductivity are lower than or equal to 1×10²⁰ atoms/cm³, and in which the photoconductivity is higher than the dark conductivity.

For example, amorphous silicon or microcrystalline silicon formed by a plasma CVD method or the like can be used for the first silicon semiconductor layer 111 and the third silicon semiconductor layer 113. Alternatively, a region which corresponds to the silicon semiconductor layer may include a crystalline silicon region and an amorphous silicon region.

A portion of the crystalline silicon region which is in contact with the single crystal silicon substrate 100 is a crystal growth region whose atomic arrangement is based on the atomic arrangement in the single crystal silicon substrate. Therefore, a clear interface is not formed between the single crystal silicon substrate and the crystalline silicon region, and thus the single crystal silicon substrate and the crystalline silicon region are substantially one region. In other words, the crystalline silicon region has approximately the same favorable crystal quality as the single crystal silicon substrate. Thus, it can be said that the crystalline silicon region is a region which contains extremely few impurities or defects.

Further, the amorphous silicon region is formed on the crystalline silicon region. The amorphous silicon region is a region which is continuously formed on the crystalline silicon region. For example, the crystalline silicon region and the amorphous silicon region are formed in such a manner that the crystalline silicon region is formed by a plasma CVD method or the like and then the amorphous silicon region is formed without steps including cleaning, transportation, and the like in between; alternatively, the formation process of the amorphous silicon region is started before the formation process of the crystalline silicon region is completed.

A region having a high impurity concentration, an oxide layer, or the like is not formed between the crystalline silicon region and the amorphous silicon region which are continuously formed without steps in between as described above, and thus a clear interface is not formed. Thus, it can be said that both the crystalline silicon region and the amorphous silicon region are substantially continuous or the phase change between the amorphous silicon region and the crystalline silicon region continuously occurs.

Note that in a region including the crystalline silicon region and the amorphous silicon region, the proportion of the crystalline silicon region is preferably higher. Note that there are many defects such as dangling bonds on a surface of crystal silicon; therefore, it is preferable that at least a surface of the crystalline silicon region be covered with an amorphous silicon region containing hydrogen so as not to be exposed in order to terminate the defects with hydrogen.

As described above, a clear interface is not formed between the single crystal silicon substrate 100 and the crystalline silicon region nor between the crystalline silicon region and the amorphous silicon region; thus, an influence of localized levels formed by defects at an interface or impurities can be removed. Further, the crystalline silicon region has few defects and the absolute amount of defects in the entire region including the crystalline silicon region and the amorphous silicon region can be reduced; thus, carrier recombination can be reduced.

Further, the surface of the crystalline silicon region has unevenness in which a distance between projections is a nanometer size and whose height is a nanometer size. Such unevenness has an effect similar to the optical effect of the unevenness described above. Accordingly, the photoelectric conversion device illustrated in each of FIGS. 1A and 1B can have a structure in which unevenness having a nanometer size is provided on a surface of the unevenness having a micrometer size, so that the electric characteristics can be greatly improved by the optical effect.

Further, in one embodiment of the present invention, the first silicon semiconductor layer 111 and the third silicon semiconductor layer 113 preferably contain as few impurity elements as possible. An atmospheric component or a cleaning gas component remaining in a deposition chamber is easily taken as an impurity into the silicon semiconductor layers formed by a plasma CVD method or the like even when a source gas is highly purified. Such an impurity forms an impurity level in an energy gap, which causes an adverse effect such as capture of carriers.

It is found from an experimental result by the present inventors that the adverse effect can be almost removed by setting a concentration of an atmospheric component such as nitrogen or oxygen contained in the first silicon semiconductor layer 111 and the third silicon semiconductor layer 113 at lower than or equal to 1×10¹⁷ atoms/cm³. Further, it is found that the concentration of fluorine which is a component of a cleaning gas, which is contained in the first silicon semiconductor layer 111 and the third silicon semiconductor layer 113 is preferably lower than or equal to the concentration of nitrogen and/or oxygen therein.

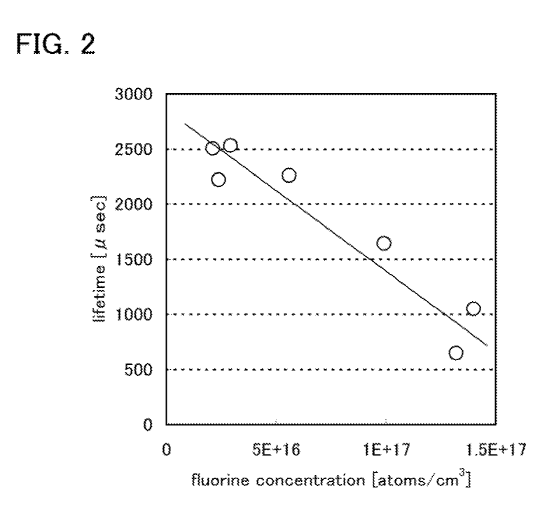

FIG. 2 shows measurement results of lifetimes of samples in each of which amorphous silicon semiconductor layers are formed on both surfaces of a single crystal silicon substrate and whose fluorine concentration in the amorphous silicon semiconductor layers varies among the samples. As the single crystal silicon substrate, an n-type single crystal silicon substrate whose oxygen concentration is lower than or equal to 8×10¹⁷ atoms/cm³ is used. The amorphous silicon semiconductor layers are formed in such a manner that deposition conditions are adjusted so that the fluorine concentration varies among the samples.

Since a single crystal silicon substrate formed using a bulk with favorable characteristics is used, the samples each have a lifetime of approximately 1000 μsec even when the fluorine concentration is high. By setting the fluorine concentration lower than or equal to 1×10¹⁷ atoms/cm³, a lifetime of longer than or equal to 1500 μsec is obtained. Further, by setting the fluorine concentration at lower than or equal to 6×10¹⁶ atoms/cm³, a lifetime of longer than or equal to 2000 μsec is obtained. Accordingly, the fluorine concentration in the silicon semiconductor layers formed as passivation layers on the surfaces of the single crystal silicon substrate is preferably lower than or equal to 1×10¹⁷ atoms/cm³, more preferably lower than or equal to 6×10¹⁶ atoms/cm³.

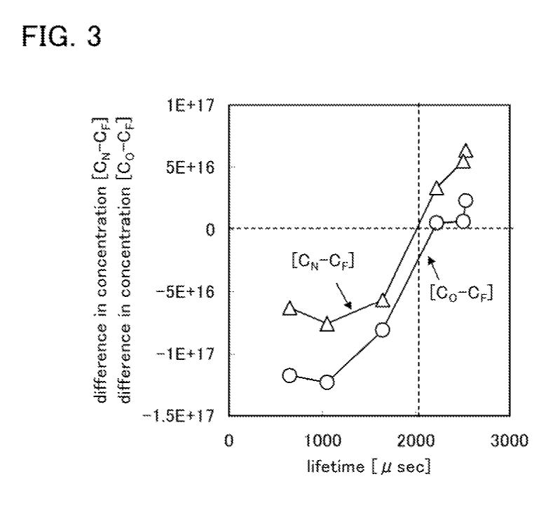

Further, the fluorine concentration of the silicon semiconductor layers is preferably lower than the nitrogen concentration and the oxygen concentration thereof. FIG. 3 shows results obtained by comparing lifetimes of plural samples each including silicon semiconductor layers which are formed on both surfaces of a single crystal silicon substrate with a difference (C_{N}−C_{F}) between the nitrogen concentration and the fluorine concentration of the silicon semiconductor layers and comparing the lifetimes of the plural samples with a difference (C_{O}−C_{F}) between the oxygen concentration and the fluorine concentration of the silicon semiconductor layers.

It is found from FIG. 3 that values of the differences (C_{N}−C_{F}) and (C_{O}−C_{F}) change from negative values to positive values at around 2000 μsec of lifetime. The case where the values are positive values means that the fluorine concentration is lower than the nitrogen concentration or the oxygen concentration, and thus it is found that positive values of the differences are a clear indication of longer lifetime.

In other words, in order to achieve a longer lifetime, it is preferable that the fluorine concentration in the silicon semiconductor layers (the passivation layers) be lower than or equal to 1×10¹⁷ atoms/m³, and in addition, that the fluorine concentration in the silicon semiconductor layers be lower than any one or both of the nitrogen concentration and the oxygen concentration of the silicon semiconductor layers. Note that in the case where the fluorine concentration of the silicon semiconductor layers is higher than or equal to 1×10¹⁷ atoms/cm³, there is no correlation between lifetime and the nitrogen concentration and between lifetime and the oxygen concentration.

The above-described silicon semiconductor layers are formed on the surfaces of the single crystal silicon substrate 100 as the first silicon semiconductor layer 111 and the third silicon semiconductor layer 113, whereby the lifetime of the single crystal silicon substrate can be improved, so that a photoelectric conversion device having favorable electric characteristics can be formed. In particular, remarkable effects are obtained in the case where the surface of the single crystal silicon substrate has unevenness.

The single crystal silicon substrate 100 has one conductivity type, and the second silicon semiconductor layer 112 is a semiconductor layer having a conductivity type opposite to that of the single crystal silicon substrate 100. In the case where the single crystal silicon substrate 100 has n-type conductivity, the second silicon semiconductor layer 112 has p-type conductivity, and a p-n junction is formed between the single crystal silicon substrate 100 and the second silicon semiconductor layer 112 with the first silicon semiconductor layer 111 provided therebetween.

The fourth silicon semiconductor layer 114 has the same conductivity type as the single crystal silicon substrate 100 and has higher carrier density than the single crystal silicon substrate 100. In one embodiment of the present invention, in the case where the single crystal silicon substrate 100 has n-type conductivity, an n-n⁺ junction is formed between the single crystal silicon substrate 100 and the fourth silicon semiconductor layer 114 with the third silicon semiconductor layer 113 provided therebetween. In other words, the fourth silicon semiconductor layer 114 serves as a back surface field (BSF) layer. When the BSF layer is formed, minority carriers are repelled by the BSF layer and attracted to the p-n junction side, whereby carrier recombination in the vicinity of the second electrode 190 can be prevented.

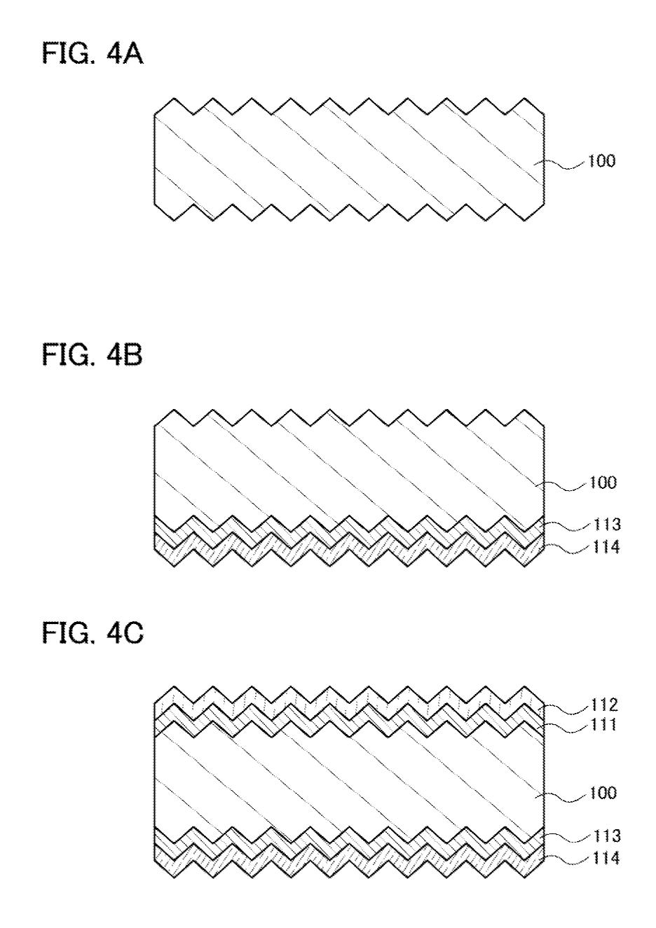

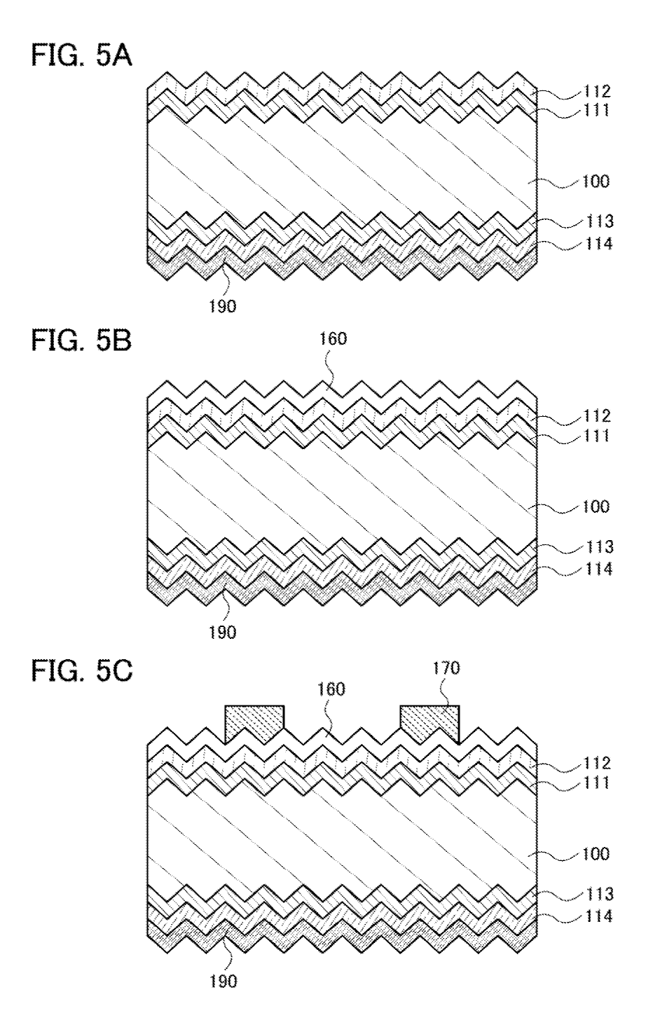

Next, a method for manufacturing the photoelectric conversion device illustrated in FIG. 1A will be described with reference to FIGS. 4A to 4C and FIGS. 5A to 5C.

In this embodiment, an n-type single crystal silicon substrate which is formed by an MCZ method and whose oxygen concentration is lower than or equal to 8×10¹⁷ atoms/cm³ is used as the single crystal silicon substrate 100. Note that there is no limitation on the manufacturing method as long as the oxygen concentration of the single crystal silicon substrate is lower than or equal to 8×10¹⁷ atoms/cm³. Further, in the case where a surface and a back surface of the single crystal silicon substrate are processed to have unevenness, a single crystal silicon substrate whose-surface is a (100) plane is used.

Next, the surface and the back surface of the single crystal silicon substrate 100 are processed to have unevenness.

In the case where the initial single crystal silicon substrate 100 is a substrate which is subjected to only a slicing process, a damage layer with a thickness of 10 μm to 20 μm, remaining on the surface of the single crystal silicon substrate 100, is removed by a wet etching process. For an etchant, an alkaline solution with a relatively high concentration, for example, a 10 to 50% sodium hydroxide aqueous solution or a 10 to 50% potassium hydroxide aqueous solution can be used. Alternatively, a mixed acid in which hydrofluoric acid and nitric acid are mixed, or the mixed acid to which acetic acid is further added may be used.

Next, impurities adhering to the surfaces of the single crystal silicon substrate from which the damage layers have been removed are removed by acid cleaning. As an acid, for example, a mixture (FPM) of 0.5% hydrofluoric acid and 1% hydrogen peroxide, or the like can be used. Alternatively, RCA cleaning or the like may be performed. Note that this acid cleaning may be omitted.

The unevenness is formed utilizing a difference in etching rates depending on plane orientations in etching of the crystalline silicon using the alkaline solution. For an etchant, an alkaline solution with a relatively low concentration, for example, a 1 to 5% sodium hydroxide aqueous solution, or a 1 to 5% potassium hydroxide aqueous solution can be used and preferably several percent isopropyl alcohol is added thereto. The temperature of the etchant is 70° C. to 90° C., and the single crystal silicon substrate is soaked in the etchant for 30 to 60 minutes. By this treatment, unevenness including a plurality of minute projections each having a substantially square pyramidal shape and recessions formed between adjacent projections can be formed on the surfaces of the single crystal silicon substrate 100.

Next, oxide layers which are uneven and formed on the surfaces of single crystal silicon substrate in the etching step for forming the unevenness are removed. Another purpose of removing the oxide layers is to remove a component of the alkaline solution, which is likely to remain in the oxide layers. When an alkali metal ion, e.g., an Na ion or a K ion enters silicon, the lifetime is decreased, and the electric characteristics of the photoelectric conversion device are drastically lowered as a result. Note that in order to remove the oxide layers, a 1 to 5% diluted hydrofluoric acid may be used.

Next, the surfaces of the single crystal silicon substrate 100 are preferably etched with a mixed acid in which hydrofluoric acid and nitric acid are mixed, or the mixed acid to which acetic acid is further added to remove impurities such as a metal component. By adding the acetic acid, an effect of keeping oxidizing power of nitric acid for stable etching, and an effect of adjusting the etching rate can be obtained. For example, the volume ratio of hydrofluoric acid, nitric acid, and acetic acid can be 1:1.5 to 3:2 to 4. Note that in this specification, the mixed acid solution containing hydrofluoric acid, nitric acid, and acetic acid is referred to as HF-nitric-acetic acid. Further, in the etching with the HF-nitric-acetic acid, angles in cross sections of vertexes of the projections are made larger, so that a surface area can be reduced, and the absolute amount of surface defects can be reduced. Note that in the case where the etching with the HF-nitric-acetic acid is performed, the above step of removing the oxide layers with diluted hydrofluoric acid can be omitted. Through the steps up to here, a cross-sectional shape of the single crystal silicon substrate illustrated in FIG. 4A is formed.

Next, after appropriate cleaning, the third silicon semiconductor layer 113 is formed on the other surface of the single crystal silicon substrate 100 by a plasma CVD method. In this embodiment, it is preferable that the third silicon semiconductor layer 113 be an i-type amorphous silicon semiconductor layer and have a thickness of greater than or equal to 3 nm and less than or equal to 50 nm.

The third silicon semiconductor layer 113 can be formed, for example, under the following conditions: monosilane is introduced to a reaction chamber; the pressure inside the reaction chamber is higher than or equal to 100 Pa and lower than or equal to 200 Pa; the electrode interval is greater than or equal to 10 mm and less than or equal to 40 mm; the power density based on the area of a cathode electrode is greater than or equal to 8 mW/cm² and less than or equal to 120 mW/cm²; and the substrate temperature is higher than or equal to 150° C. and lower than or equal to 300° C.

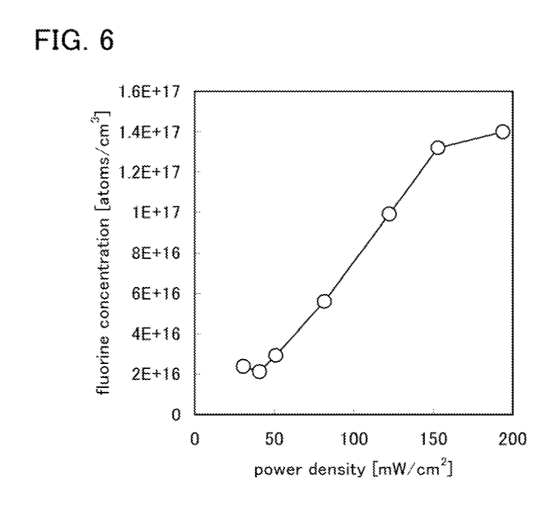

Note that as shown in FIG. 6, the fluorine concentration in the silicon semiconductor layers depends strongly on the power density during the deposition. Accordingly, in order to reduce the fluorine concentration, the power density is less than or equal to 120 mW/cm², preferably less than or equal to 80 mW/cm², more preferably less than or equal to 50 mW/cm². For example, the following conditions maybe used: the pressure inside the reaction chamber is 150 Pa, the electrode interval is 10 mm, the power density is 40 mW/cm², and the substrate temperature is 250° C.

Next, the fourth silicon semiconductor layer 114 is formed on the third silicon semiconductor layer 113 (see FIG. 4B). The thickness of the fourth silicon semiconductor layer 114 is preferably greater than or equal to 3 nm and less than or equal to 50 nm. In this embodiment, the fourth silicon semiconductor layer 114 is n-type amorphous silicon and has a film thickness of 10 nm.

The fourth silicon semiconductor layer 114 can be formed under the following conditions: monosilane and a hydrogen-based phosphine (0.5%) are introduced to a reaction chamber at a flow rate ratio of 1:1 to 50; the pressure inside the reaction chamber is higher than or equal to 100 Pa and lower than or equal to 200 Pa; the electrode interval is greater than or equal to 10 mm and less than or equal to 40 mm; the power density based on the area of a cathode electrode is greater than or equal to 8 mW/cm² and less than or equal to 120 mW/cm²; and the substrate temperature is higher than or equal to 150° C. and lower than or equal to 300° C.

Next, the first silicon semiconductor layer 111 is formed on the one surface of the single crystal silicon substrate 100 by a plasma CVD method. The thickness of the first silicon semiconductor layer 111 is preferably greater than or equal to 3 nm and less than or equal to 50 nm. In this embodiment, the first silicon semiconductor layer 111 has a thickness of 5 nm. The first silicon semiconductor layer 111 can be formed under conditions similar to those of the third silicon semiconductor layer 113.

Next, the second silicon semiconductor layer 112 is formed on the first silicon semiconductor layer 111 (see FIG. 4C). The thickness of the second silicon semiconductor layer 112 is preferably greater than or equal to 3 nm and less than or equal to 50 nm. In this embodiment, the second silicon semiconductor layer 112 is p-type amorphous silicon and has a film thickness of 10 nm.

The second silicon semiconductor layer 112 can be formed under the following conditions: monosilane and hydrogen-based diborane (0.1%) are introduced to a reaction chamber at a flow rate ratio of 1:2 to 50; the pressure inside the reaction chamber is higher than or equal to 100 Pa and lower than or equal to 200 Pa; the electrode interval is greater than or equal to 8 mm and less than or equal to 40 mm; the power density based on the area of a cathode electrode is greater than or equal to 8 mW/cm² and less than or equal to 50 mW/cm²; and the substrate temperature is higher than or equal to 150° C. and lower than or equal to 300° C.

Note that in this embodiment, an RF power source with a frequency of 60 MHz, with which a source gas is decomposed with high efficiency, is preferably used as a power source used for forming the silicon semiconductor layers. The decomposition efficiency of the source gas is enhanced, whereby dangling bonds on the surfaces of the single crystal silicon substrate 100 are easily terminated with hydrogen in forming the first silicon semiconductor layer 111 and the third silicon semiconductor layer 113. Note that an RF power source with a frequency of 13.56 MHz, 27.12 MHz, or 100 MHz may also be used. Furthermore, the silicon semiconductor layers may be formed by pulsed discharge as well as by continuous discharge. The implementation of pulse discharge controlled in such a manner that power supply is turned on and off or controlled in such a manner that the pulse is set at a high level and a low level can improve the film quality and reduce particles produced in the gas phase.

Next, the second electrode 190 is formed on the fourth silicon semiconductor layer 114 (see FIG. 5A). The second electrode 190 can be formed using a low-resistance metal such as silver, aluminum, or copper by a sputtering method, a vacuum evaporation method, or the like. Alternatively, the second electrode 190 may be formed using a conductive resin such as a silver paste or a copper paste by a screen printing method.

Next, the light-transmitting conductive film 160 is formed on the second silicon semiconductor layer 112 by a sputtering method (see FIG. 5B). For the light-transmitting conductive film 160, the following can be used: indium tin oxide; indium tin oxide containing silicon; indium oxide containing zinc; zinc oxide; zinc oxide containing gallium; zinc oxide containing aluminum; tin oxide; tin oxide containing fluorine; tin oxide containing antimony; graphene, or the like. The light-transmitting conductive film 160 is not limited to a single layer, and may be a stacked layer of different films. For example, a stacked layer of an indium tin oxide and a zinc oxide containing aluminum, a stacked layer of an indium tin oxide and a tin oxide containing fluorine, etc. can be used. The total film thickness is greater than or equal to 10 nm and less than or equal to 1000 nm.

Note that the formation order of the films provided, on the surface and the back surface of the single crystal silicon substrate 100 is not limited to the order described above as long as the structure illustrated in FIG. 5B can be obtained. For example, the first silicon semiconductor layer 111 may be formed, and then the third silicon semiconductor layer 113 may be formed.

Next, by a screen printing method, a conductive resin is applied on the light-transmitting conductive film 160 and is baked, so that the first electrode 170 is formed. Note that the conductive resin used here may be a silver paste, a copper paste, a nickel paste, a molybdenum paste, or the like. Further, the first electrode 170 may be a stacked layer of different materials, such as a stacked layer of a silver paste and a copper paste.

As described above, according to one embodiment of the present invention, a photoelectric conversion device having excellent electric characteristics can be formed.

### EXAMPLE

In this example, cell characteristics of a photoelectric conversion device will be described.

The photoelectric conversion device described in this example has a structure illustrated in FIG. 1A and was manufactured by the method described in the above embodiment using an n-type single crystal silicon substrate which was manufactured by an MCZ method and has an oxygen concentration of lower than or equal to 8×10¹⁷ atoms/cm³. The size of the cell is 0.7 cm². Simulated solar radiation (a solar spectrum was AM 1.5, and irradiation intensity was 100 mW/cm³) generated by a solar simulator was used for the measurement.

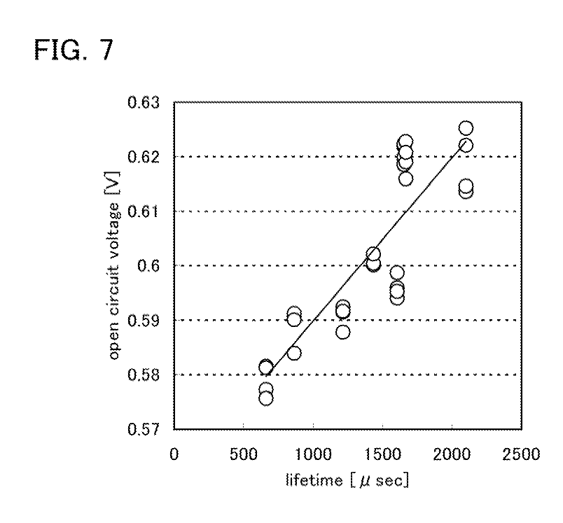

FIG. 7 shows the relation between lifetimes of samples each having the structure illustrated in FIG. 4C in which amorphous silicon layers are provided on both surfaces of a single crystal silicon substrate and junction layers are provided on the amorphous silicon layers and open circuit voltages (Voc) calculated by measuring the current-voltage (I-V) characteristics of the samples each having the structure illustrated in FIG. 5C in which a light-transmitting conductive film and an electrode are formed. Note that the samples whose, lifetimes are different from one another were formed by changing the power density in deposition of the amorphous silicon layers.

As shown in FIG. 7, it was confirmed that there is a strong correlation between the open circuit voltage and the lifetime, and that it is particularly effective to achieve the lifetime of longer than or equal to 1500 μsec. Accordingly, it was proved that one embodiment of the present invention contributes to improvement in the conversion efficiency of a photoelectric conversion device.

This example can be freely combined with the embodiment.

This application is based on Japanese Patent Application serial no. 2011-132101 filed with Japan Patent Office on Jun. 14, 2011, the entire contents of which are hereby incorporated by reference.

What is claimed is:

1. A photoelectric conversion device comprising:
a single crystal silicon substrate having one conductivity type;
a first silicon semiconductor layer which is in contact with one surface of the single crystal silicon substrate;
a second silicon semiconductor layer which is in contact with the first silicon semiconductor layer and has a conductivity type opposite to that of the single crystal silicon substrate;
a third silicon semiconductor layer which is in contact with the other surface of the single crystal silicon substrate; and
a fourth silicon semiconductor layer which is in contact with the third silicon semiconductor layer, has the same conductivity type as the single crystal silicon substrate, and has a higher carrier density than the single crystal silicon substrate,
wherein a fluorine concentration in the first silicon semiconductor layer and the third silicon semiconductor layer is lower than or equal to 1×10¹⁷ atoms/cm³.

2. The photoelectric conversion device according to claim 1, wherein the single crystal silicon substrate has n-type conductivity.

3. The photoelectric conversion device: according to claim 1, wherein an oxygen concentration in the single crystal silicon substrate is lower than or equal to 8×10¹⁷ atoms/cm³.

4. The photoelectric conversion device according to claim 1, wherein the fluorine concentration in the first silicon semiconductor layer is lower than a nitrogen concentration in the first silicon semiconductor layer.

5. The photoelectric conversion device according to claim 1, wherein the fluorine concentration in the third silicon semiconductor layer is lower than a nitrogen concentration in the third silicon semiconductor layer.

6. The photoelectric conversion device according to claim 1, wherein the fluorine concentration in the first silicon semiconductor layer is lower than an oxygen concentration in the first silicon semiconductor layer.

7. The photoelectric conversion device according to claim 1, wherein the fluorine concentration in the third silicon semiconductor layer is lower than an oxygen concentration in the third silicon semiconductor layer.

8. The photoelectric conversion device according to claim 1,
wherein the fluorine concentration in the first silicon semiconductor layer is lower than a nitrogen concentration in the first silicon semiconductor layer, and
wherein the fluorine concentration in the first silicon semiconductor layer is lower than an oxygen concentration in the first silicon semiconductor layer.

9. The photoelectric conversion device according to claim 1,
wherein the fluorine concentration in the third silicon semiconductor layer is lower than a nitrogen concentration in the third silicon semiconductor layer, and
wherein the fluorine concentration in the third silicon semiconductor layer is lower than an oxygen concentration in the third silicon semiconductor layer.

10. A photoelectric conversion device comprising:
a single crystal silicon substrate having one conductivity type;
a first silicon semiconductor layer which is in contact with one surface of the single crystal silicon substrate;
a second silicon semiconductor layer which is in contact with the first silicon semiconductor layer and has a conductivity type opposite to that of the single crystal silicon substrate;
a light-transmitting conductive film which is in contact with the second silicon semiconductor layer;
a first electrode which is in contact with the light-transmitting conductive film;
a third silicon semiconductor layer which is in contact with the other surface of the single crystal silicon substrate;
a fourth silicon semiconductor layer which is in contact with the third silicon semiconductor layer, has the same conductivity type as the single crystal silicon substrate, and has a higher carrier density than the single crystal silicon substrate; and
a second electrode which is in contact with the fourth silicon semiconductor layer,
wherein a fluorine concentration in the first silicon semiconductor layer and the third silicon semiconductor layer is lower than or equal to 1×10¹⁷ atoms/cm³.

11. The photoelectric conversion device according to claim 10, wherein the single crystal silicon substrate has n-type conductivity.

12. The photoelectric conversion device according to claim 10, wherein an oxygen concentration in the single crystal silicon substrate is lower than or equal to 8×10¹⁷ atoms/cm³.

13. The photoelectric conversion device according to claim 10, wherein the fluorine concentration in the first silicon semiconductor layer is lower than a nitrogen concentration in the first silicon semiconductor layer.

14. The photoelectric conversion device according to claim 10, wherein the fluorine concentration in the third silicon semiconductor layer is lower than a nitrogen concentration in the third silicon semiconductor layer.

15. The photoelectric conversion device according to claim 10, wherein the fluorine concentration in the first silicon semiconductor layer is lower than an oxygen concentration in the first silicon semiconductor layer.

16. The photoelectric conversion device according to claim 10, wherein the fluorine concentration in the third silicon semiconductor layer is lower than an oxygen concentration in the third silicon semiconductor layer.

17. The photoelectric conversion device according to claim 10,
wherein the fluorine concentration in the first silicon semiconductor layer is lower than a nitrogen concentration in the first silicon semiconductor layer, and
wherein the fluorine concentration in the first silicon semiconductor layer is lower than an oxygen concentration in the first silicon semiconductor layer.

18. The photoelectric conversion device according to claim 10,
wherein the fluorine concentration in the third silicon semiconductor layer is lower than a nitrogen concentration in the third silicon semiconductor layer, and
wherein the fluorine concentration in the third silicon semiconductor layer is lower than an oxygen concentration in the third silicon semiconductor layer.

19. The photoelectric conversion device according to claim 10, wherein at least one of the first electrode and the second electrode comprises a grid electrode.

20. The photoelectric conversion device according to claim 10, wherein the one surface of the single crystal silicon substrate has a plurality of projections.
